(19) United States
(12) Patent Application Publication
(10) Pub. No.: US 2010/0103610 A1
(43) Pub. Date: Apr. 29, 2010

(54) PORTABLE ELECTRONIC DEVICE

(75) Inventor: SHIH-CHIEH LIN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: CHI MEI COMMUNICATION SYSTEMS, INC., Tu-Cheng City (TW)

(21) Appl. No.: 12/422,361

(22) Filed: Apr. 13, 2009

(30) Foreign Application Priority Data
Oct. 24, 2008 (CN) 200810305178.1

(51) Int. Cl. H05K 5/00; H01R 13/46

(52) U.S. Cl. 361/679.55; 439/892

(57) ABSTRACT

A portable electronic device includes a housing having a standing portion, and an RF connector cover disposed in the housing. The RF connector cover includes a connecting portion fixed to the housing and a supporting portion connected to the connecting portion. The connecting portion of the RF connector cover is rotatable relative to the housing to stand the electronic device with a cooperative support of the RF connector cover and the standing portion of the housing.

### BACKGROUND

1. Technical Field

The present disclosure relates to portable electronic devices, and particularly, to a portable electronic device with a radio frequency connector cover.

2. Description of the Related Art

With the development of wireless communication and information processing technologies, portable mobile terminals, such as mobile phones and personal digital assistants (PDAs), are now in widespread use.

Typically, the portable electronic device includes a housing and a display panel. Some portable electronic devices cannot stand on a table without an external support due to their thin body configuration. Some portable electronic devices may have an extra supporting assembly attached to the housing to stand the display panel on the table. However, the extra supporting assembly of the portable electronic device tends to become bulky and complicated.

What is needed, therefore, is a new portable electronic device to overcome the above-described shortcomings.

### BRIEF DESCRIPTION OF THE DRAWINGS

Many aspects of the present portable electronic device can be better understood with reference to the following drawings. The components in the drawings are not necessarily drawn to scale, the emphasis instead being placed upon clearly illustrating the principles of the present portable electronic device. Moreover, in the drawings, like reference numerals designate corresponding parts throughout the several views.

FIG. 1 is an isometric view of an embodiment of an electronic device, the electronic device including a housing, and a radio frequency (RF) connector cover.

FIG. 2 is similar to FIG. 1, but viewed from another aspect.

FIG. 3 is a partial, enlarged, exploded view of the electronic device of FIG. 2.

FIG. 4 is a side, enlarged, cross-sectional view of the electronic device of FIG 2 taken along line IV-IV

FIG. 5 is a partial, cross-sectional view of the electronic device of FIG. 4 showing the RF connector cover slid out from the electronic device.

FIG. 6 is similar to FIG. 5, but showing the RF connector cover rotated at an angle.

FIG. 7 is similar to FIG. 1, but showing the RF connector cover slid out from the electronic device.

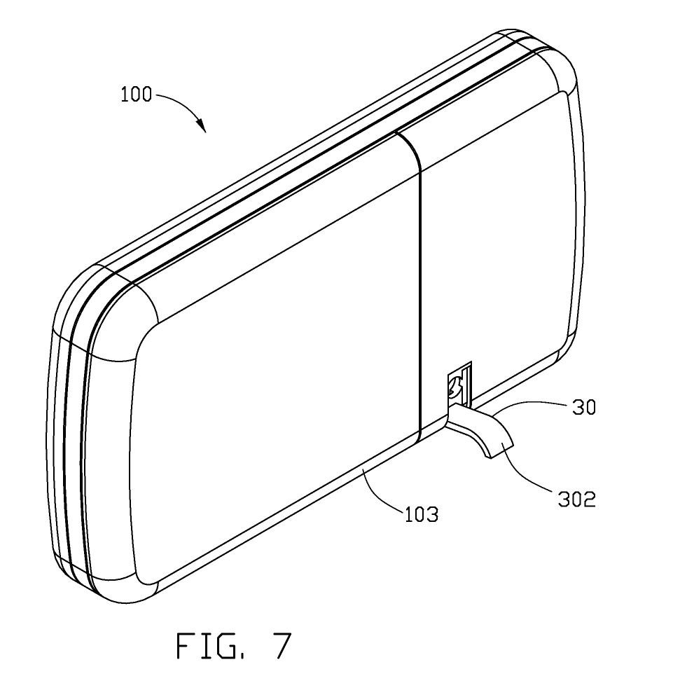

### DETAILED DESCRIPTION

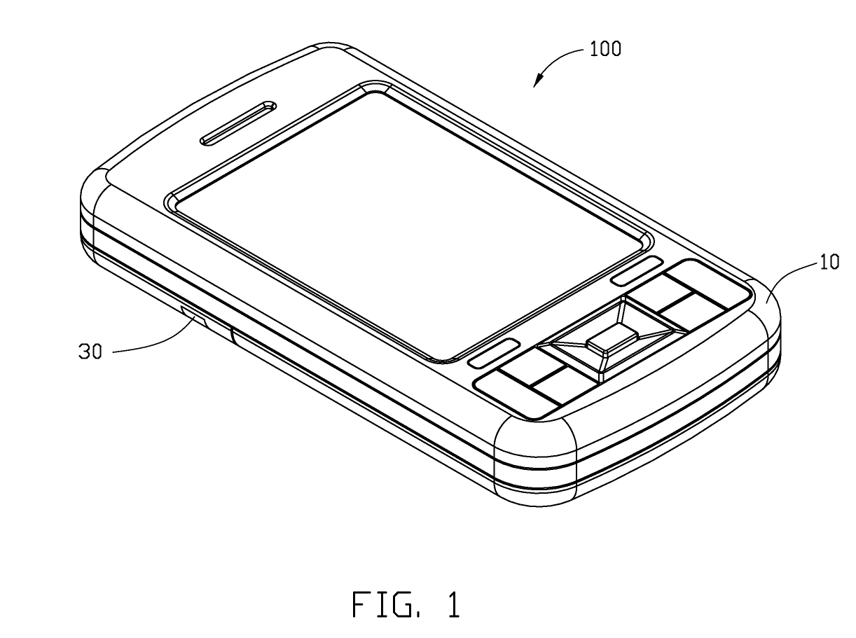

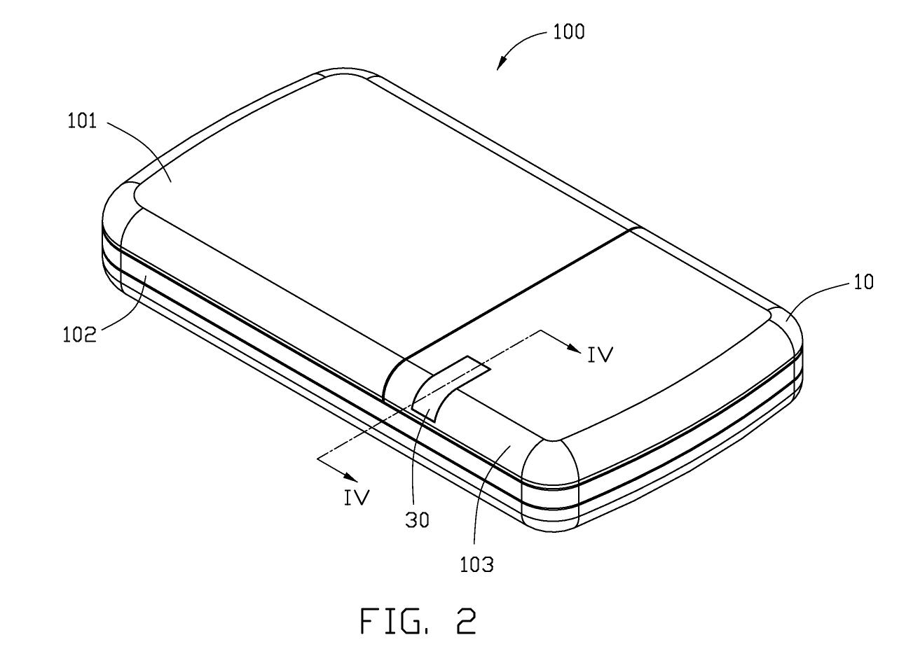

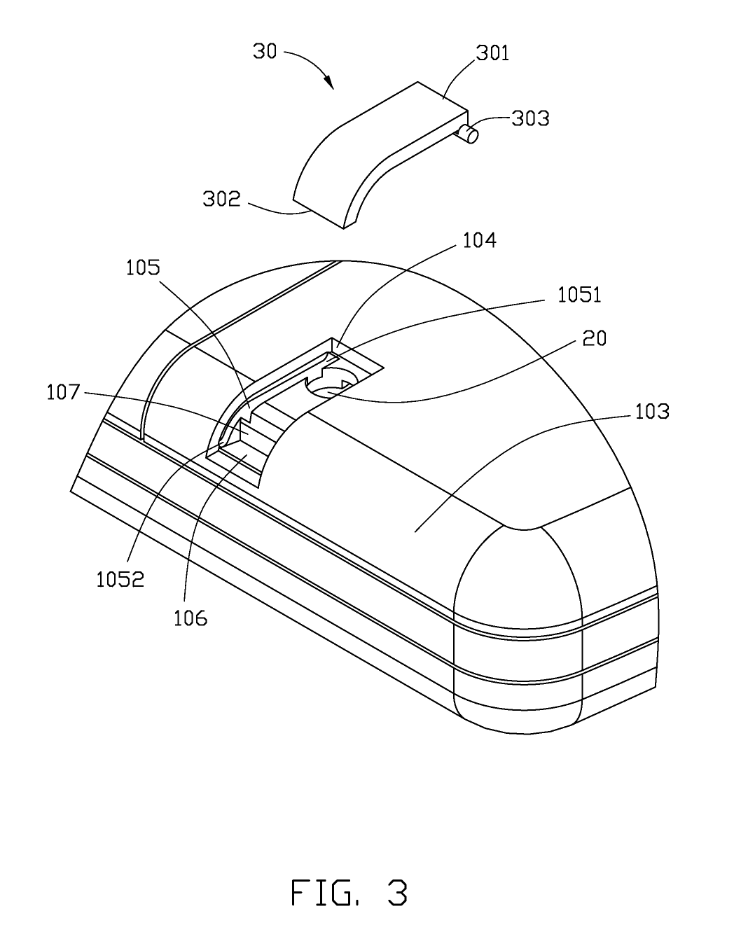

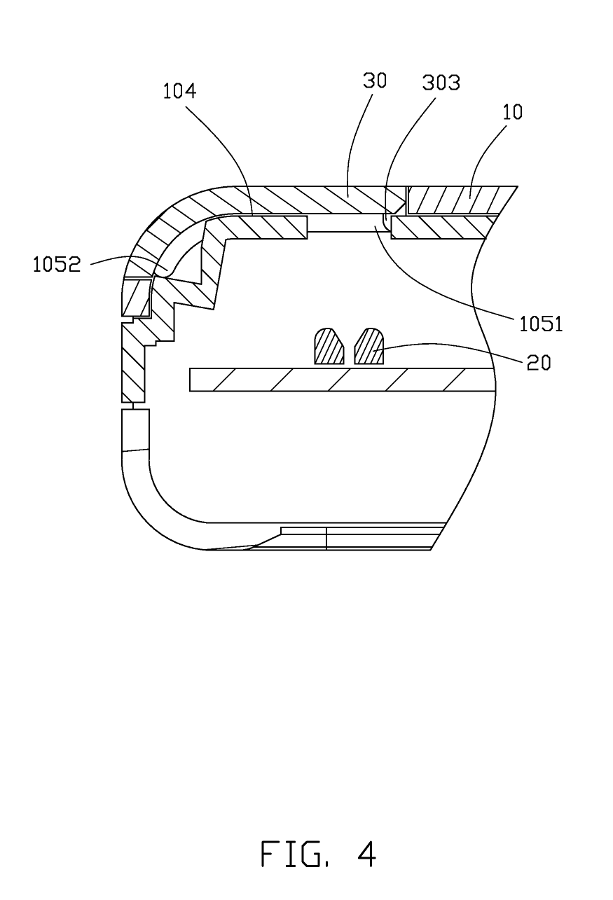

Referring to FIGS. 1 through 4, an embodiment of a portable electronic device 100 includes a housing 10, a radio frequency (RF) connector 20 (see FIG. 4) and an RF connector cover 30. In this embodiment, the portable electronic device 100 is a mobile phone.

The housing 10 may be substantially rectangular cuboid shaped. The housing 10 includes an upper surface 101, a side surface 102, and a joint surface 103 interconnecting the upper surface 101 and the side surface 102. The joint surface 103 may be an arcuate surface. In this embodiment, the joint surface 103 of the housing 10 is a standing portion of the portable electronic device 100. The housing 10 defines an opening 104 in the upper surface 101, the housing 10 extending through the standing portion to receive the RF connector cover 30. The housing 10 includes two elongated sliding grooves 105 defined in two opposite inner sidewalls of the opening 104. Each elongated sliding groove 105 includes a locking portion 1051 at one end away from the joint surface 103, and a rotary portion 1052 at the other end. The RF connector 20 is disposed in one end of the opening 104 away from the joint surface 103. The housing 10 further includes a stepped depression 106 defined in the other end of the opening 104 adjacent to the joint surface 103. The stepped depression 106 includes a restricting surface 107.

The RF connector cover 30 is an elongated sheet to cover the opening 104. The RF connector cover 30 includes a connecting portion 301, and a supporting portion 302 connected to the supporting portion 301. The connecting portion 301 includes two rotary shafts 303 extending outwardly from opposite side surfaces of the RF connector cover 30. The two rotary shafts 303 of the connecting portion 301 rotatably lock into the locking portions 1051 of the two elongated sliding grooves 105, such that the RF connector cover 30 is fixed to the housing 10 and covers the opening 104. In this embodiment, a shape of the free end of the supporting portion 302 complements the joint surface to 103 to form an integral appearance.

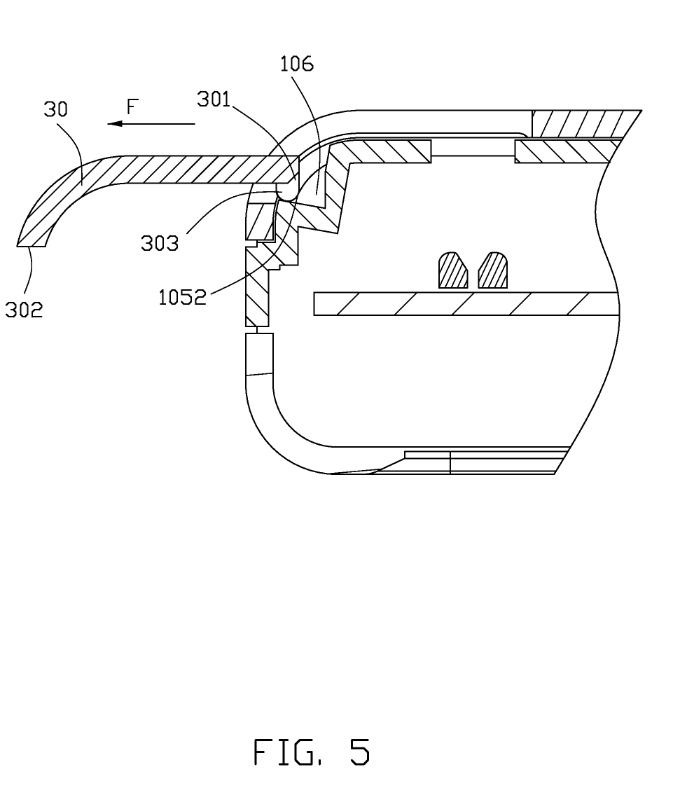

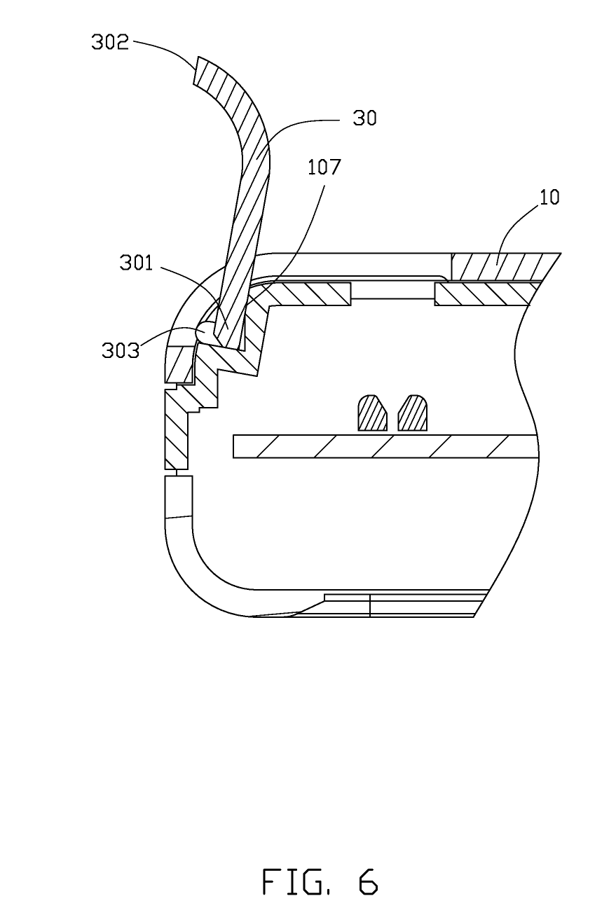

Referring to FIGS. 5 and 6, when a user want to stand the portable electronic device 100, the RF connector cover 30 can be slid with an external force in a direction F along the elongated sliding grooves 105. When the connecting portion 301 reaches the rotary portions 1052 of the elongated sliding grooves 105, the supporting portion 302 is substantially parallel to the upper surface 101 of the housing 10 and apart from the side surface 102. When the supporting portion 302 is pressed upward, and the connecting portion 301 is rotated relative to the rotary portions 1052 in the stepped depression 106, such that the supporting portion 302 is partially located above an upper surface 101 of the housing 10, the RF connector cover 30 resists the restricting surface 107 of the stepped depression 106. Thus, the portable electronic device 100 stands by being supported by the RF connector cover 30 and the standing portion (the joint surface 103) of the portable electronic device 100.

In addition, the RF connector cover 30 can be repositioned to cover the opening 104 by rotating the supporting portion 302 to a position substantially parallel with the upper surface 101 and sliding the RF connector cover 30 along the elongated sliding groove 105 until the connecting portion 301 is locked into the locking portion 1051.

The RF connector cover 30 may be made of materials such as acrylonitrile-butadiene-styrene (ABS), polycarbonate (PC) and any combination thereof. A material of the RF connector cover 30 should have a suitable mechanical strength to support the portable electronic device 100.

It should be pointed out that the elongated sliding grooves 105 can be replaced by two rotary holes to receive the rotary shafts 303 of the RF connector cover 30. The RF connector cover 30 can be rotated an angle relative to the upper surface 101 of the housing 10 to stand the portable electronic device 100 with the standing portion thereof.

The RF connector cover 30 serves two functions. It covers the RF connector 20 and helps to stand the portable electronic device 100 on a flat surface. The portable electronic device 100 does not need any extra support structure attached to the housing 10.

It is to be understood that the joint surface 103 can be omitted, and the standing portion of the portable electronic device 100 can be a side surface 102.

Finally, while the present disclosure has been described with reference to particular embodiments, the description is illustrative of the disclosure and is not to be construed as limiting the disclosure. Therefore, various modifications can be made to the embodiments by those of ordinary skill in the art without departing from the true spirit and scope of the disclosure as defined by the appended claims.

What is claimed is:

1. A portable electronic device, comprising:
a housing comprising a standing portion;
a radio frequency (RF) connector cover disposed in the housing, the RF connector cover comprising a connecting portion fixed to the housing and a supporting portion connected to the connecting portion, the connecting portion is rotatable relative to the housing to stand the electronic device with a cooperative support of the RF connector cover and the standing portion of the housing.

2. The portable electronic device of claim 1, wherein the housing further comprises an upper surface and a side surface; the standing portion is a joint surface interconnecting the upper surface and the side surface.

3. The portable electronic device of claim 2, wherein the housing defines an opening in the upper surface, the opening extending through the standing portion to receive the RF connector cover.

4. The portable electronic device of claim 3, wherein the housing further comprises two elongated sliding grooves defined in two opposite inner sidewalls of the opening, each elongated sliding groove comprises a locking portion at one end thereof away from the joint surface, and a rotary portion at the other end thereof.

5. The portable electronic device of claim 4, wherein the connecting portion comprises two rotary shafts extending outwardly from two opposite side surfaces of the RF connector cover, the two rotary shafts are rotatably locked into the locking portions of the two elongated sliding grooves.

6. The portable electronic device of claim 2, wherein the housing further comprises a stepped depression defined in one end of the opening adjacent to the joint surface; the stepped depression comprises a restricting surface; the connecting portion can be rotated relative to the rotary portions in the stepped depression.

7. The portable electronic device of claim 2, wherein a shape of the free end of the supporting portion complements the joint surface to form an integral appearance.

8. The portable electronic device of claim 1, wherein the RF connector cover is made of materials selected from the group consisting of acrylonitrile-butadiene-styrene, polycarbonate, and any combination thereof.

9. The portable electronic device of claim 2, wherein the joint surface is an arcuate surface.

10. The portable electronic device of claim 3, wherein the housing further comprises two rotary holes defined in two opposite inner sidewalls of the opening; the connecting portion comprises two rotary shafts extending outwardly from two opposite side surfaces of the RF connector cover, the two rotary shafts are rotatably locked into the two rotary holes.

11. A portable electronic device, comprising:
a housing comprising an upper surface and a side surface adjoining the upper surface, the upper surface defining an opening;
an RF connector cover disposed on the upper surface to cover the opening, the RF connector cover is a sheet member, wherein one end of the RF connector cover is rotatable relative to the housing to stand the electronic device with a cooperative support of the RF connector cover and the side surface.

12. The portable electronic device of claim 11, wherein the housing further comprises two elongated sliding grooves defined in two opposite inner sidewalls of the opening, each elongated sliding groove comprises a locking portion at one end thereof away from the joint surface, and a rotary portion at the other end thereof.

13. The portable electronic device of claim 12, wherein the RF connector cover comprises two rotary shafts extending outwardly from two opposite side surfaces of the RF connector cover, the two rotary shafts are rotatably locked into the locking portions of the two elongated sliding grooves.

14. The portable electronic device of claim 12, wherein the housing further comprises a stepped depression defined in one end of the opening adjacent to the side surface; the stepped depression comprises a restricting surface; the RF connector cover can be rotated relative to the rotary portions in the stepped depression.

15. The portable electronic device of claim 11, wherein the RF connector cover is made of materials selected from the group consisting of acrylonitrile-butadiene-styrene, polycarbonate, and any combination thereof.
